(19) United States
(12) Patent Application Publication
(10) Pub. No.: US 2023/0276627 A1
(43) Pub. Date: Aug. 31, 2023

(54) SEMICONDUCTOR DEVICE AND MANUFACTURING METHOD THEREOF

(71) Applicant: Kioxia Corporation, Tokyo (JP)

(72) Inventors: Takashi FUKUSHIMA, Yokkaichi Mie (JP); Kaihei KATOU, Yokkaichi Mie (JP); Kenichiro TORATANI, Yokkaichi Mie (JP); Ryota FUJITSUKA, Yokkaichi Mie (JP); Junya FUJITA, Nagoya Aichi (JP); Atsushi FUKUMOTO, Kuwana Mie (JP); Motoki FUJII, Yokkaichi Mie (JP); Yuki WAKISAKA, Yokkaichi Mie (JP); Kazuya HATANO, Nagoya Aichi (JP)

(73) Assignee: Kioxia Corporation, Tokyo (JP)

(21) Appl. No.: 17/901,606

(22) Filed: Sep. 1, 2022

(30) Foreign Application Priority Data
Feb. 25, 2022 (JP) 2022-028571

(51) Int. Cl. H01L 27/11582

(52) U.S. Cl. CPC H01L 27/11582

(57) ABSTRACT

A semiconductor device according to the present embodiment comprises a stack including a plurality of electrode films stacked in a first direction to be separated from each other. A column portion extends in the stack in the first direction and includes a semiconductor layer, and has memory cells at respective intersections of the semiconductor layer and the electrode films. A dividing portion extends in the stack in the first direction and a second direction crossing the first direction, divides the electrode films in a third direction crossing the first direction and the second direction, and includes an insulator. A first film is provided between the insulator and an end surface in the third direction of each of the electrode films and contains a first metal and silicon.

### CROSS REFERENCE TO RELATED APPLICATIONS

This application is based upon and claims the benefit of priority from the prior Japanese Patent Application No. 2022-028571, filed on Feb. 25, 2022, the entire contents of which are incorporated herein by reference.

### FIELD

The embodiments of the present invention relate to a semiconductor device and manufacturing method thereof.

### BACKGROUND

A semiconductor storage device such as a NAND flash memory may include a three-dimensional memory cell array including a plurality of memory cells arranged three-dimensionally. The three-dimensional memory cell array includes a plurality of word lines that are stacked and electrically isolated from each other. While a metal material is used for the word lines, if the metal material is oxidized, the resistance of the word lines is increased.

### BRIEF DESCRIPTION OF THE DRAWINGS

FIG. 1 is a schematic perspective view of an example of a semiconductor device according to a first embodiment;

FIG. 2 is a schematic plan view of a stack in FIG. 1;

FIGS. 3 and 4 are schematic cross-sectional views of an example of a memory cell having a three-dimensional configuration;

FIG. 5 is a plan view illustrating a configuration example of a boundary between the memory cell array and the stair portion;

FIG. 6 is a cross-sectional view illustrating a configuration example of a portion of the memory cell array according to the first embodiment, including the deep slit and its surroundings;

FIG. 7 is a cross-sectional view illustrating a more detailed configuration example of the slit and the electrode film;

FIGS. 8A and 8B are conceptual diagrams illustrating a function of the metal silicide film with respect to oxygen;

FIGS. 9 to 14 are cross-sectional views illustrating an example of the manufacturing method of the semiconductor storage device according to the first embodiment;

FIG. 15A is a cross-sectional view illustrating a configuration example of the semiconductor storage device according to a second embodiment;

FIG. 15B is a cross-sectional view illustrating a configuration example of the semiconductor storage device according to a modification of the second embodiment;

FIG. 16 is a cross-sectional view illustrating a configuration example of the semiconductor storage device according to a third embodiment;

FIG. 17 is a cross-sectional view illustrating a configuration example of the semiconductor storage device according to a fourth embodiment;

FIGS. 18 to 21 are cross-sectional views illustrating an example of a manufacturing method of the semiconductor storage device according to the fourth embodiment;

FIG. 22 is a block diagram illustrating a configuration example of a semiconductor storage device to which any of the embodiments described above is applied; and

FIG. 23 is a circuit diagram illustrating an example of a circuit configuration of the memory cell array.

### DETAILED DESCRIPTION

Embodiments will now be explained with reference to the accompanying drawings. The present invention is not limited to the embodiments. In the embodiments, “an upper direction” or “a lower direction” occasionally differs from an upper direction or a lower direction based on a gravitational acceleration direction. In the present specification and the drawings, elements identical to those described in the foregoing drawings are denoted by like reference characters and detailed explanations thereof are omitted as appropriate.

A semiconductor device according to the present embodiment comprises a stack including a plurality of electrode films stacked in a first direction to be separated from each other. A column portion extends in the stack in the first direction and includes a semiconductor layer, and has memory cells at respective intersections of the semiconductor layer and the electrode films. A dividing portion extends in the stack in the first direction and a second direction crossing the first direction, divides the electrode films in a third direction crossing the first direction and the second direction, and includes an insulator. A first film is provided between the insulator and an end surface in the third direction of each of the electrode films and contains a first metal and silicon.

### First Embodiment

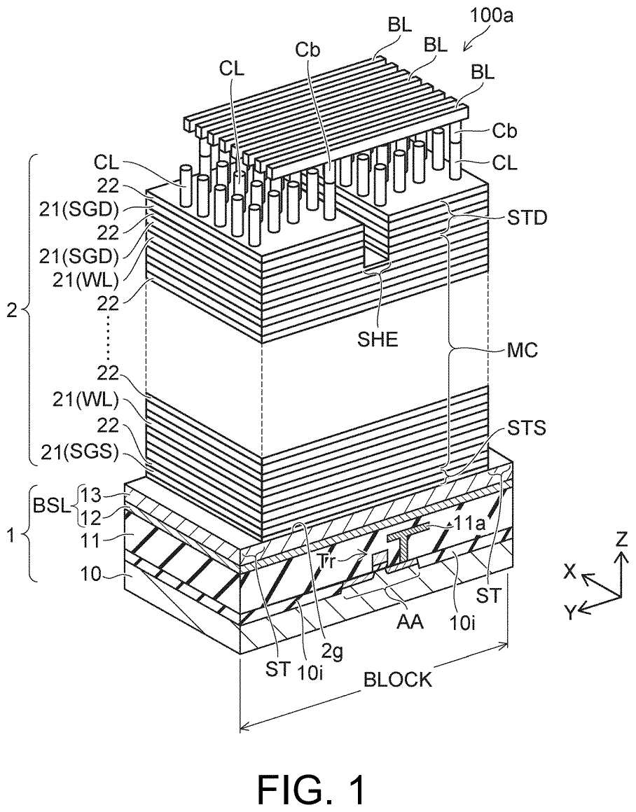

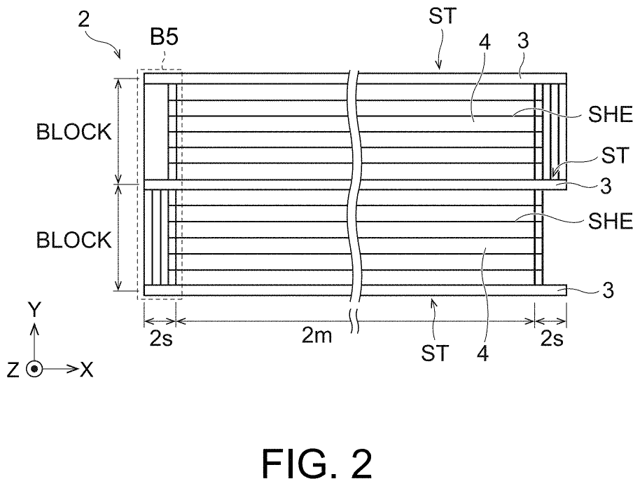

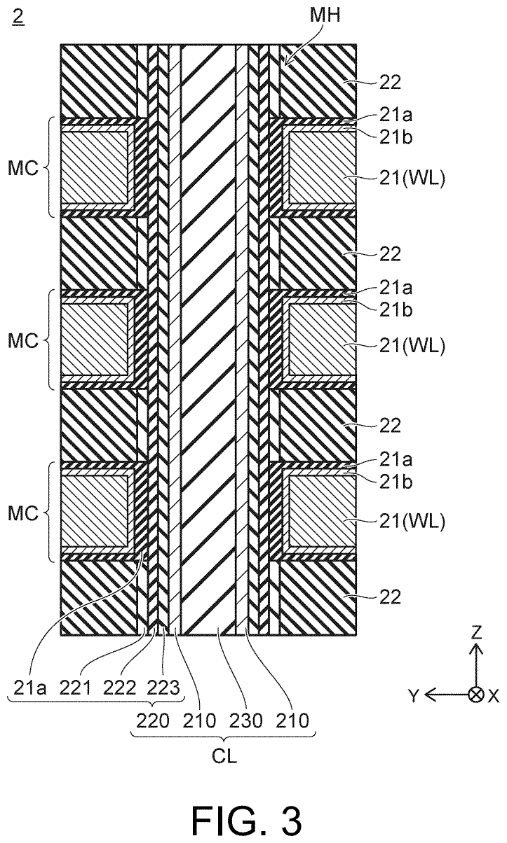

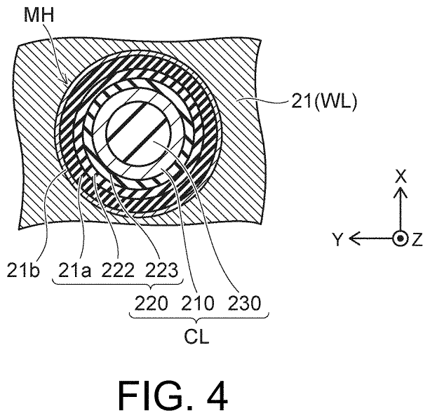

FIG. 1 is a schematic perspective view of an example of a semiconductor device (for example, a semiconductor storage device 100a) according to a first embodiment. FIG. 2 is a schematic plan view of a stack 2 in FIG. 1. In the present specification, a stacking direction of the stack 2 refers to the Z-direction. One direction that crosses the Z-direction, for example, at right angles refers to the Y-direction. One direction that crosses the Z-direction and the Y-direction, for example, at right angles refers to the X-direction. FIGS. 3 and 4 are schematic cross-sectional views of an example of a memory cell having a three-dimensional configuration.

As illustrated in FIGS. 1 to 4, the semiconductor storage device 100a according to the first embodiment is a non-volatile memory including memory cells having a three-dimensional configuration.

The semiconductor storage device 100a includes a base portion 1, the stack 2, a deep slit ST (a plate-shaped portion 3), a shallow slit SHE (a plate-shaped portion 4), and a plurality of column portions CL.

The base portion 1 includes a substrate 10, an interlayer dielectric film 11, a conductive layer 12, and a semiconductor portion 13. The interlayer dielectric film 11 is provided on the substrate 10. The conductive layer 12 is provided on the interlayer dielectric film 11. The semiconductor portion 13 is provided on the conductive layer 12.

The substrate 10 is a semiconductor substrate, for example, a silicon substrate. The conductivity type of silicon (Si) is, for example, a p-type. An element isolation region 10i, for example, is provided in a surface region of the substrate 10. The element isolation region 10i is an insulating region that contains, for example, silicon oxide (SiO₂) and defines an active area AA in the surface region of the substrate 10. Source and drain regions of a transistor Tr are provided in the active area AA. The transistor Tr configures a peripheral circuit (a CMOS (Complementary Metal Oxide Semiconductor) circuit) of the non-volatile memory. The CMOS circuit is provided below a built-in source layer BSL and on the substrate 10. The interlayer dielectric film 11 contains, for example, silicon oxide and insulates the transistor Tr. A wire 11a is provided in the interlayer dielectric film 11. A portion of the wire 11a is electrically connected to the transistor Tr. The conductive layer 12 contains a conductive metal, for example, tungsten (W) or molybdenum (Mo). The semiconductor portion 13 contains, for example, silicon. The conductivity type of silicon is an n-type, for example. The semiconductor portion 13 may be formed by a plurality of layers, and a portion thereof may contain undoped silicon. Further, either the conductive layer 12 or the semiconductor portion 13 may be omitted.

The conductive layer 12 and the semiconductor portion 13 serve as a common source line of a memory cell array (2m in FIG. 2). The conductive layer 12 and the semiconductor portion 13 are electrically connected to each other as an integrated conductive film and are also referred to as “built-in source layer BSL” collectively.

The stack 2 is provided above the substrate 10 and is located in the Z-direction with respect to the conductive layer 12 and the semiconductor portion 13 (the built-in source layer BSL). The stack 2 is configured by a plurality of electrode films 21 and a plurality of insulation films 22 alternately stacked in the Z-direction as a first direction. The electrode films 21 contain a conductive metal, for example, tungsten (W), ruthenium (Ru), cobalt (Co), molybdenum (Mo), nickel (Ni), or titanium (Ti) and are separated and electrically isolated from each other. The insulation films 22 contain, for example, silicon oxide. The insulation films 22 electrically isolate the electrode films 21 from each other. The stacked number of each of the electrode films 21 and the insulation films 22 may be any number. The insulation films 22 may be air gaps, for example. An insulation film 2g, for example, is provided between the stack 2 and the semiconductor portion 13. The insulation film 2g contains, for example, silicon oxide. The insulation film 2g may contain a high dielectric material having a higher relative permittivity than silicon oxide. The high dielectric material may be metal oxide, for example.

The electrode films 21 include at least one source-side selection gate SGS, a plurality of word lines WL, and at least one drain-side selection gate SGD. The source-side selection gate SGS is a gate electrode of a source-side selection transistor STS. The word lines WL are gate electrodes of memory cells MC. The drain-side selection gate SGD is a gate electrode of a drain-side selection transistor STD. The source-side selection gate SGS is provided in a lower region of the stack 2. The drain-side selection gate SGD is provided in an upper region of the stack 2. The lower region refers to a region of the stack 2 closer to the base portion 1, and the upper region refers to a region of the stack 2 farther from the base portion 1. The word lines WL are provided between the source-side selection gate SGS and the drain-side selection gate SGD.

The thickness in the Z-direction of one of the insulation films 22 which insulates the source-side selection gate SGS and the word line WL from each other may be larger than the thickness in the Z-direction of the insulation film 22 that insulates the word lines WL from each other, for example. Further, a cover insulation film (not illustrated) may be provided on the uppermost insulation film 22 that is the farthest from the base portion 1. The cover insulation film contains silicon oxide, for example.

The semiconductor storage device 100a includes the plural memory cells MC connected in series between the source-side selection transistor STS and the drain-side selection transistor STD. The configuration in which the source-side selection transistor STS, the memory cells MC, and the drain-side selection transistor STD are connected in series is called “memory string” or “NAND string”. The memory string is connected to a bit line BL, for example, via a contact Cb. The bit line BL is provided above the stack 2 and extends in the Y-direction.

The deep slits ST and the shallow slits SHE are provided in the stack 2. The deep slits ST are provided in the stack 2, extend in the X-direction crossing the Z-direction in plan view as viewed in the Z-direction, and penetrate through the stack 2 in the Z-direction from the top end of the stack 2 to the base portion 1. The deep slits ST divide the stack 2 in the Y-direction crossing the Z-direction and the X-direction. The plate-shaped portion 3 is a wire provided in each deep slit ST (FIG. 2). The plate-shaped portion 3 is configured by an insulation film provided on the inner wall of the deep slit ST and a conductive film (not illustrated in FIG. 2) provided inside the insulation film and embedded in the deep slit ST. The conductive film in the deep slit ST is electrically isolated from the stack 2 by the insulation film and is electrically connected to the built-in source layer BSL. For the insulation film, an insulating material, for example, a silicon oxide film, is used. For the conductive film, a metal material, for example, tungsten is used. The plate-shaped portion 3 is filled with an insulation material, for example, a silicon oxide film in some cases. Meanwhile, the shallow slits SHE extend in the X-direction and are provided from the top end of the stack 2 to the middle of the stack 2. The shallow slits SHE penetrate through the upper region of the stack 2 in which the drain-side selection gate SGD is provided. The plate-shaped portion 4, for example, is provided in each shallow slit SHE (FIG. 2). The plate-shaped portion 4 is silicon oxide, for example.

As illustrated in FIG. 2, the stack 2 includes a stair portion 2s and the memory cell array 2m. The stair portion 2s is provided at an edge of the stack 2. The memory cell array 2m is sandwiched between the stair portions 2s or surrounded by the stair portions 2s. The deep slit ST is provided from the stair portion 2s at one end of the stack 2 to the stair portion 2s at the other end of the stack 2 through the memory cell array 2m. The shallow slit SHE is provided at least in the memory cell array 2m.

A portion of the stack 2 sandwiched between the two plate-shaped portions 3 illustrated in FIG. 2 is called block (BLOCK). The block configures, for example, the minimum unit for erasing data. The plate-shaped portion 4 is provided in the block. The stack 2 between the plate-shaped portion 3 and the plate-shaped portion 4 is called “finger”. The drain-side selection gate SGD is divided for each finger. Therefore, in data writing and data reading, one finger in a block can be selected by the drain-side selection gate SDG.

As illustrated in FIG. 3, each of the column portions CL is provided in a memory hole MH formed in the stack 2. Each column portion CL penetrates through the stack 2 from the top end of the stack 2 along the Z-direction and is provided in the stack 2 and in the built-in source layer BSL. Each of the column portions CL includes a semiconductor body 210, a memory film 220, and a core layer 230. The column portion CL includes the core layer 230 provided at its center, the semiconductor body 210 provided around the core layer 230, and the memory film 220 provided around the semiconductor body 210. The semiconductor body 210 is electrically connected to the built-in source layer BSL. The memory film 220 as a charge storage member has a charge trapping portion between the semiconductor body 210 and the electrode film 21. The column portions CL selected one by one from the respective fingers are connected to one bit line BL in common via the contacts Cb. Each column portion CL is provided in a cell region (Cell), for example.

As illustrated in FIG. 4, the shape of the memory hole MH in an X-Y plane is, for example, circular or elliptical. A block insulation film 21a that configures a portion of the memory film 220 may be provided between the electrode film 21 and the insulation film 22. The block insulation film 21a is, for example, a silicon oxide film, a silicon nitride film, or a metal oxide film. An example of the metal oxide is aluminum oxide. A barrier film 21b may be provided between the electrode film 21 and the insulation film 22 and between the electrode film 21 and the memory film 220. In a case where the electrode film 21 is made of, for example, tungsten (W), ruthenium (Ru), cobalt (Co), molybdenum (Mo), nickel (Ni), or titanium (Ti), titanium nitride or aluminum oxide, for example, is selected as the barrier film 21b. The block insulation film 21a prevents back tunneling of electric charges from the electrode film 21 toward the memory film 220. The barrier film 21b improves adhesion between the electrode film 21 and the block insulation film 21a.

The semiconductor body 210 has a shape of a tube with a bottom, for example, and is provided in the stack 2 to extend in the Z-direction. The semiconductor body 210 contains, for example, silicon. This silicon is polysilicon obtained by crystallizing amorphous silicon, for example. The semiconductor body 210 is made of, for example, undoped silicon. The semiconductor body 210 may be made of p-type silicon. The semiconductor body 210 serves as a channel of each of the drain-side selection transistor STD, the memory cell MC, and the source-side selection transistor STS.

A portion of the memory film 220, other than the block insulation film 21a, is provided between the inner wall of the memory hole MH and the semiconductor body 210. The shape of the memory film 220 is, for example, tubular. The memory cells MC each has a storage region between the semiconductor body 210 and the electrode film 21 that serves as the word line WL, and are provided to respectively correspond to intersections of the semiconductor body 210 and the electrode films 21. The memory cells MC are stacked in the Z-direction along each column portion CL. The memory film 220 includes a cover insulation film 221, a charge trapping film 222, and a tunnel insulation film 223, for example. The semiconductor body 210, the charge trapping film 222, and the tunnel insulation film 223 extend in the Z-direction.

The cover insulation film 221 is provided between the insulation film 22 and the charge trapping film 222. The cover insulation film 221 contains silicon oxide, for example. The cover insulation film 221 protects the charge trapping film 222 from being etched in replacement of sacrifice films (not illustrated) with the electrode films 21 (in a replacement process). The cover insulation film 221 may be removed from between the electrode film 21 and the memory film 220 in the replacement process. In this case, the block insulation film 21a, for example, is provided between the electrode film 21 and the charge trapping film 222, as illustrated in FIGS. 3 and 4. The cover insulation film 221 may not be included in a case where the replacement process is not used for forming the electrode film 21.

The charge trapping film 222 is provided between the block insulation film 21a and the cover insulation film 221, and the tunnel insulation film 223. The charge trapping film 222 contains silicon nitride, for example, and has trap sites that trap electric charges therein. A portion of the charge trapping film 222, sandwiched between the electrode film 21 serving as the word line WL and the semiconductor body 210, configures a storage region of the memory cell MC as a charge trapping portion. A threshold voltage of the memory cell MC is changed depending on whether any electric charge is present in the charge trapping portion or in accordance with the amount of the electric charges trapped in the charge trapping portion. In this manner, the memory cell MC retains information.

The tunnel insulation film 223 is provided between the semiconductor body 210 and the charge trapping film 222. The tunnel insulation film 223 contains silicon oxide, or silicon oxide and silicon nitride, for example. The tunnel insulation film 223 is a potential barrier between the semiconductor body 210 and the charge trapping film 222. For example, when electrons are injected from the semiconductor body 210 to the charge trapping portion (in a write operation) and when holes are injected from the semiconductor body 210 to the charge trapping portion (in an erase operation), the electrons and the holes each pass (tunnel) through the potential barrier formed by the tunnel insulation film 223.

The core layer 230 is embedded in a space within the tubular semiconductor body 210. The shape of the core layer 230 is columnar, for example. The core layer 230 contains silicon oxide, for example, and is insulative.

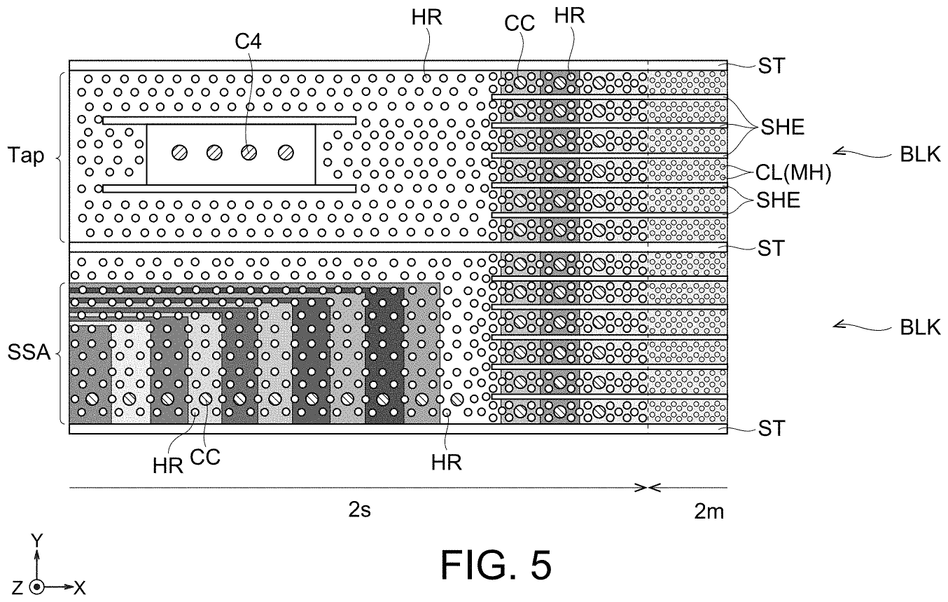

FIG. 5 is a plan view illustrating a configuration example of a boundary between the memory cell array 2m and the stair portion 2s. The column portions CL are provided in the memory holes MH in the memory cell array 2m. FIG. 5 illustrates a planar layout in a broken-line frame B5 in FIG. 2, although the scale differs.

Each column portion CL is provided in the memory hole MH provided in the stack 2. The memory hole MH penetrates through the stack 2 from the top end of the stack 2 along the stacking direction of the stack 2 (Z-axis direction) and extends in the stack 2 and in the semiconductor portion 13. Each column portion CL includes the semiconductor body 210 as a semiconductor column, the memory film 220, and the core layer 230 as illustrated in FIGS. 3 and 4. The semiconductor body 210 extends in the stack 2 in the stacking direction (Z direction) of the stack 2 and is electrically connected to the semiconductor portion 13. The memory film 220 has a charge trapping portion between the semiconductor body 210 and the electrode film 21. The column portions CL selected one by one from the respective fingers are connected to one bit line BL in common via the contacts Cb in FIG. 1. The column portions CL are provided in the memory cell array 2m.

In the stair portion 2s other than the memory cell array 2m, a tap region Tap and a stair region SSA are provided. The tap region Tap is provided in a block BLK adjacent to the stair region SSA in the Y-direction with the deep slit ST arranged therebetween. The tap region Tap may be provided between cell regions in the X-direction. The stair region SSA may be also provided between the cell regions in the X-direction. The stair region SSA is a region where a plurality of contact plugs CC are provided. The stair region SSA may include a bridge region electrically connecting the word lines WL in the plural blocks BLK that are adjacent to each other in the X-direction with the stair region SSA arranged therebetween. The tap region Tap is a region where a contact plug C4 is provided. The contact plugs CC and C4 each extend in the Z-axis direction, for example. Each contact plug CC is electrically connected to, for example, the electrode film 21 (that is, the word line WL). The contact plug C4 is electrically connected to, for example, the wire 11a for power supply to the transistor Tr or the like. A low-resistance metal such as copper or tungsten is used for the contact plugs CC and C4. The shallow slits SHE extend in the memory cell array 2m in the X-direction and electrically isolate the drain-side selection gate SGD for every finger.

A plurality of insulator columns HR are provided around the contact plug CC. Each insulator column HR is provided in a hole provided in the stack 2. The insulator column HR penetrates through the stack 2 from the top end of the stack 2 along the Z-axis direction and is provided in the stack 2 and in the semiconductor portion 13. An insulator such as a silicon oxide film is used for the insulator column HR. Each insulator column HR may have the same configuration as the column portion CL. The insulator columns HR are provided in the tap region Tap and the stair region SSA, for example. The insulator columns HR serve as support members for maintaining gaps formed in the stair region and the tap region in replacement of sacrifice films (not illustrated) with the electrode film 21 (in a replacement process). The insulator column HR has a larger diameter (width in the X-direction or the Y-direction) than the column portion CL.

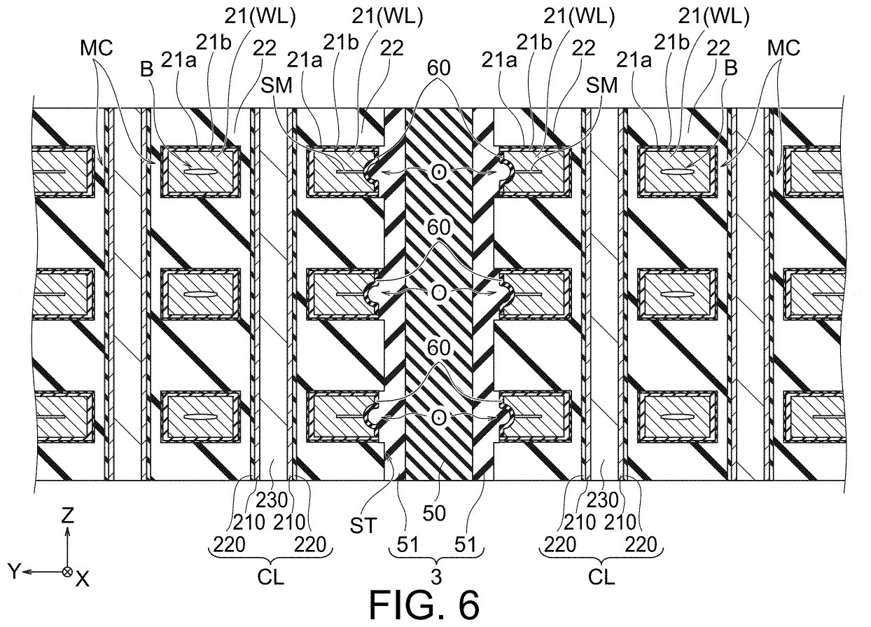

FIG. 6 is a cross-sectional view illustrating a configuration example of a portion of the memory cell array 2m according to the first embodiment, including the deep slit ST and its surroundings.

The deep slit ST (hereinafter, also simply “slit ST”) extends in the X-direction in a X-Y plane as illustrated in FIG. 2, and extends in the Z-direction in the stack 2 from the top end of the stack 2 to the base portion 1 to penetrate through the stack 2 as illustrated in FIG. 6. The slit ST serves as a dividing portion that divides the stack 2 in the Y-direction. The plate-shaped portion 3 includes an insulation member or a wire 50 and an insulation film 51. The insulation film 51 is provided on the inner wall of the slit ST. For the insulation film 51, an insulating material, for example, a silicon oxide film, is used. The insulation member or the wire 50 is provided inside the insulation film 51 in the slit ST. In a case where the insulation member or the wire 50 is an insulation member, the plate-shaped portion 3 serves as an insulating portion that electrically isolates the electrode films 21 of the stack 2. In this case, an insulating material, for example, a silicon oxide film, is used for the insulation member 50. In a case where the insulation member or the wire 50 is a wire, the wire 50 is electrically insulated from the electrode films 21 of the stack 2 by the insulation film 51 provided on the inner wall of the slit ST, and is embedded in the slit ST and electrically connected to the built-in source layer BSL. In this case, a conductive material, for example, tungsten is used for the wire 50.

In the present embodiment, a metal silicide film 60 is provided between the electrode film 21 (the word line WL) and the plate-shaped portion 3 in the slit ST. The metal silicide film 60 is provided between the insulation film 51 and a Y-direction end surface of the electrode film 21 and contains a metal and silicon. The metal silicide film 60 is provided to cover an opposed surface of the electrode film 21, which is opposed to the insulation film 51 of the plate-shaped portion 3. For example, any of tungsten silicide (WSi), ruthenium silicide (RuSi), cobalt silicide (CoSi), molybdenum silicide (MoSi), nickel silicide (NiSi), and titanium silicide (TiSi) is used for the metal silicide film 60. The thickness of the metal silicide film 60 is, for example, about 5 angstroms to 5 nanometers (nm).

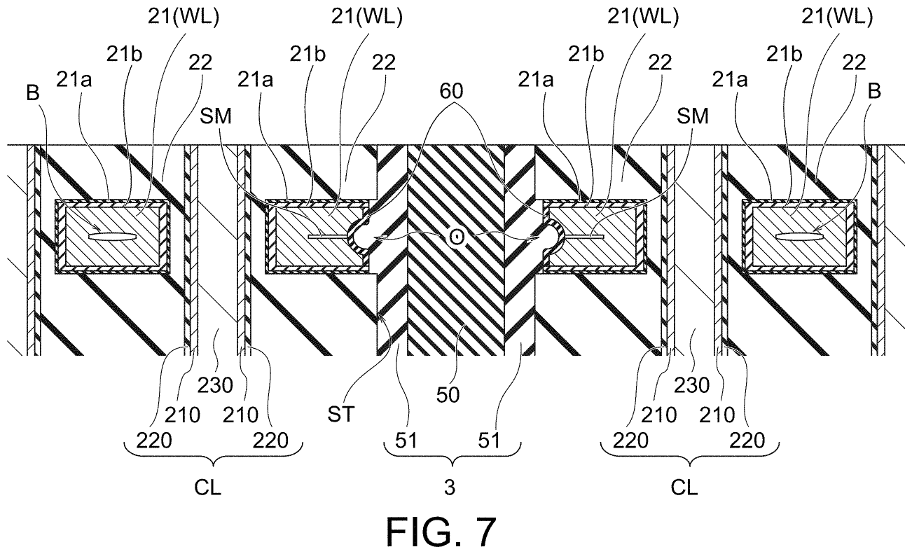

FIG. 7 is a cross-sectional view illustrating a more detailed configuration example of the slit ST and the electrode film 21. The electrode film 21 is provided with a void B and/or a seam SM as a cavity portion. The metal silicide film 60 is provided on a surface (a side surface) of the electrode film 21 on the slit ST side. The metal silicide film 60 is provided between the electrode film 21 and the insulation film 51 of the plate-shaped portion 3 and extends in the X-direction along the electrode film 21. Therefore, the metal silicide film 60 covers the entire side surface of the electrode film 21 which is exposed to the side close to the slit ST and the plate-shaped portion 3. Accordingly, oxygen O can be prevented from entering into the electrode film 21 via the slit ST.

When oxygen O enters into the electrode film 21, the electrode film 21 is oxidized. For example, in a case where the electrode film 21 is made of molybdenum, the electrode film 21 is turned into molybdenum oxide. In a case where the electrode film 21 is made of tungsten, the electrode film 21 is turned into tungsten oxide. When a portion of the electrode film 21 is turned into metal oxide, the resistance of the electrode film 21 (the word line WL) is increased.

Meanwhile, according to the present embodiment, the metal silicide film 60 is provided between the insulation film 51 in the slit ST and the electrode film 21 and covers the side surface of the electrode film 21 which is exposed to the slit ST. With this configuration, the metal silicide film 60 prevents entrance of oxygen O into the electrode film 21 from the slit ST. As a result, oxidation of the electrode film 21 can be prevented, so that increase of the resistance of the word line WL can be prevented. By maintaining the resistance of the word line WL at a low level, reduction of an operating speed of the semiconductor storage device 100a can be prevented.

In a case where the metal silicide film 60 is made of molybdenum silicide MoxSiy (x and y are positive numbers), the metal silicide film 60 may be made of MoSi₂ or Mo₅Si₃, for example.

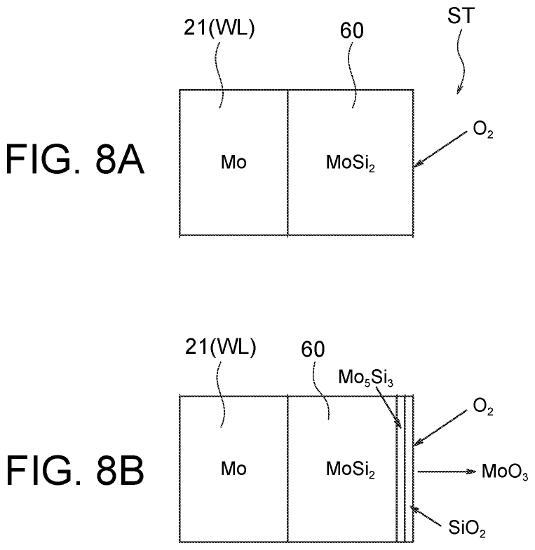

FIGS. 8A and 8B are conceptual diagrams illustrating a function of the metal silicide film 60 with respect to oxygen O₂. The following descriptions will be provided assuming that the metal silicide film 60 is a molybdenum silicide film (MoSi₂).

When oxygen O₂ attempts to enter to the electrode film 21 covered by the metal silicide film 60 from the slit ST as illustrated in FIG. 8A, a silicon oxide film and a molybdenum silicide film (Mo₅Si₃) are formed in the surface of the metal silicide film 60 as illustrated in FIG. 8B. Further, molybdenum oxide MoO₃ is dissociated from the surface of the metal silicide film 60. Accordingly, oxygen O₂ is consumed only in the surface of the metal silicide film 60 but is not diffused to the electrode film 21. Consequently, oxidation of the electrode film 21 can be prevented, so that the resistance of the electrode film 21 (the word line WL) can be maintained at a low level.

Next, a manufacturing method of the semiconductor storage device 100a according to the first embodiment is described.

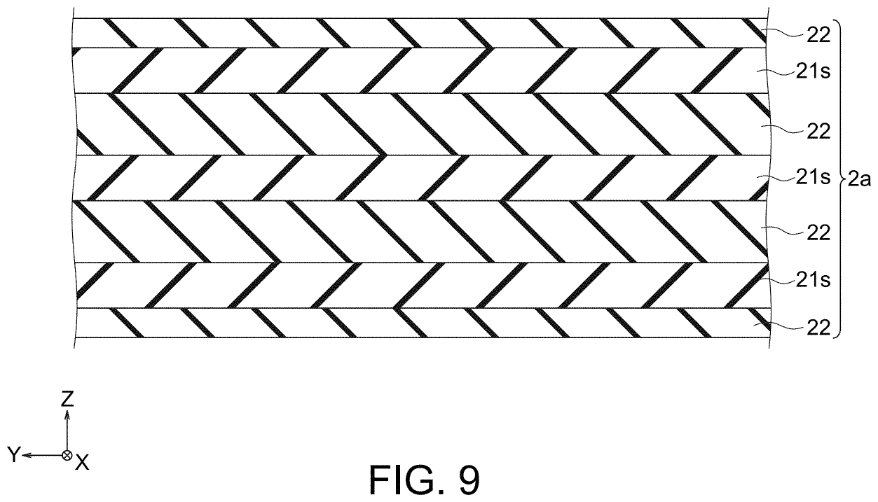

FIGS. 9 to 14 are cross-sectional views illustrating an example of the manufacturing method of the semiconductor storage device 100a according to the first embodiment. FIGS. 9 to 14 illustrate a cross-section of the memory cell array 2m in a region including the slit ST and its surroundings.

First, the base portion 1 in FIG. 1 is formed. Next, as illustrated in FIG. 9, the conductive layer 12 or the semiconductor portion 13 as a portion of the built-in source layer BSL is formed in a upper part of the base portion 1, and a stack 2a of the insulation films 22 and sacrifice films 21s is formed on the conductive layer 12 or the semiconductor portion 13. For the insulation films 22, an insulating material, for example, a silicon oxide film, is used. For the sacrifice films 21s, an insulating material that can be selectively etched with respect to the insulation film 22, for example, a silicon nitride film is used. The sacrifice films 21s are replaced with a conductive material for the electrode films 21 in a replacement process to be performed later.

Next, the memory holes MH are formed by lithography and etching in order to form the column portions CL. The memory holes MH are provided in the stack 2a and extend in a stacking direction of the insulation films 22 and the sacrifice films 21s (Z-direction). The memory holes MH are formed to penetrate through the stack 2a and reach the semiconductor portion 13 under the stack 2a. The memory holes MH may be substantially circular or substantially elliptical in plan view as viewed in the Z-direction.

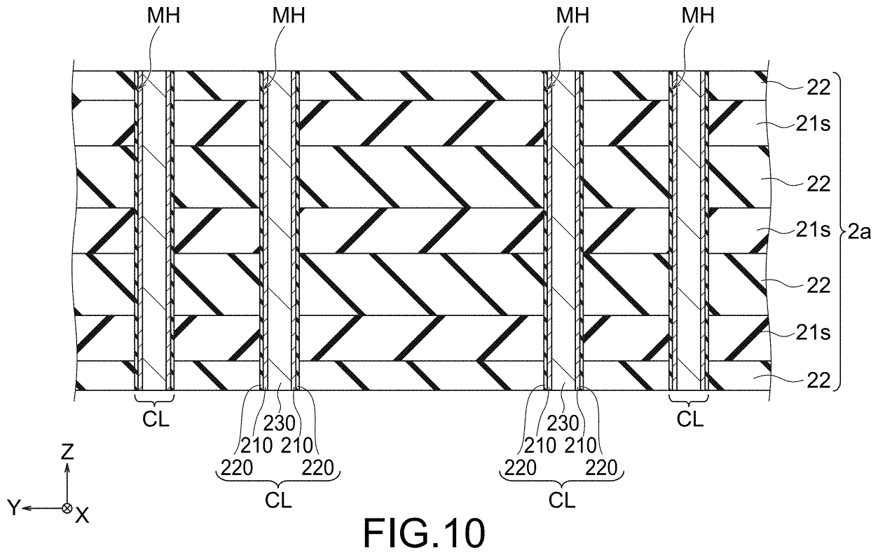

Next, the memory film 220 and the semiconductor body 210 are deposited on the inner wall of each memory hole MH in this order. Further, the core layer 230 is filled in the memory hole MH inside the memory film 220 and the semiconductor body 210. Accordingly, the column portion CL is formed in the stack 2a as illustrated in FIG. 10. The column portion CL extends in the stack 2a in the Z-direction, penetrates through the stack 2a, and reaches the semiconductor portion 13 under the stack 2a. In this manner, the semiconductor body 210 is electrically connected to the built-in source layer BSL in FIG. 1.

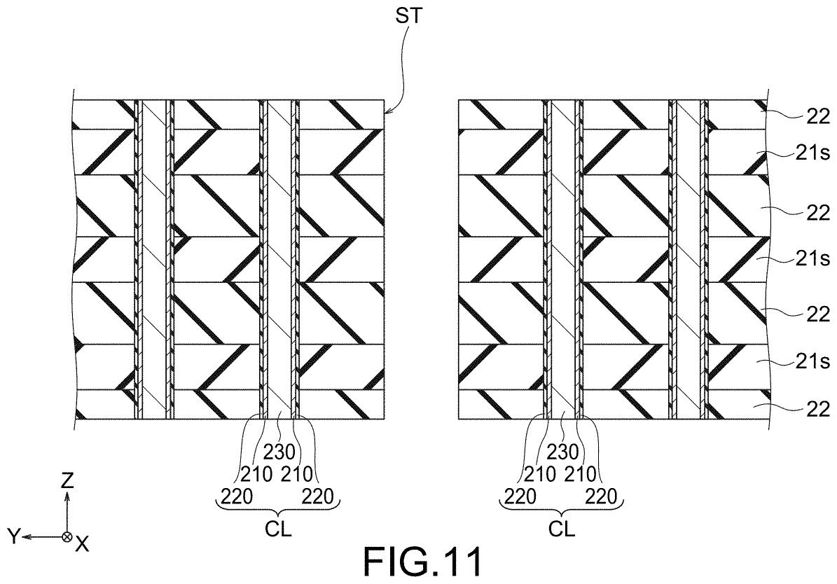

Next, the slit ST is formed by lithography and etching, whereby the structure illustrated in FIG. 11 is obtained. The slit ST penetrates through the stack 2a and reaches the conductive layer 12 and the semiconductor portion 13. In plan view as viewed in the Z-direction, as described with reference to FIG. 2, the slit ST extends in the X-direction.

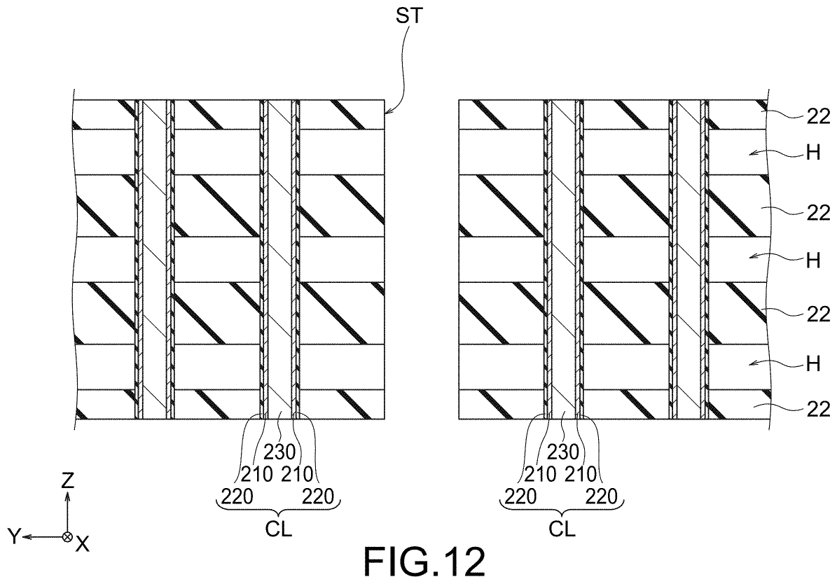

Next, as illustrated in FIG. 12, the sacrifice films 21s are removed via the slit ST. Accordingly, cavities H are formed in regions where the sacrifice films 21s have been provided.

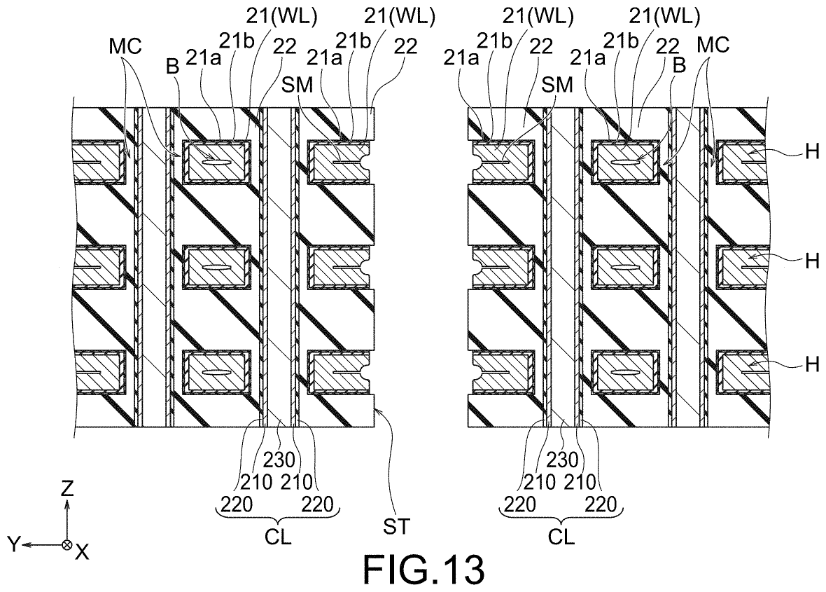

Next, as illustrated in FIG. 13, the block insulation film 21a and the barrier film 21b are formed on the inner wall of each cavity H. As the block insulation film 21a, a silicon oxide film, a silicon nitride film, or a metal oxide film is used, for example. For the barrier film 21b, titanium nitride or aluminum oxide is used, for example. Further, a material for the electrode films 21 is embedded inside the block insulation film 21a and the barrier film 21b in the cavity. For the electrode films 21, tungsten (W), ruthenium (Ru), cobalt (Co), molybdenum (Mo), nickel (Ni), or titanium (Ti) is used, for example. The electrode films 21 serve as, for example, the word lines WL. The material for the electrode films 21 is filled in each cavity H via the slit ST, and a seam or the void B may be generated within that material.

As described above, the sacrifice films 21s are replaced with a low-resistance metal material, for example, tungsten, whereby the electrode films 21 are formed. This process is also called “replacement process”. The replacement process converts the stack 2a to the stack 2 in FIG. 1.

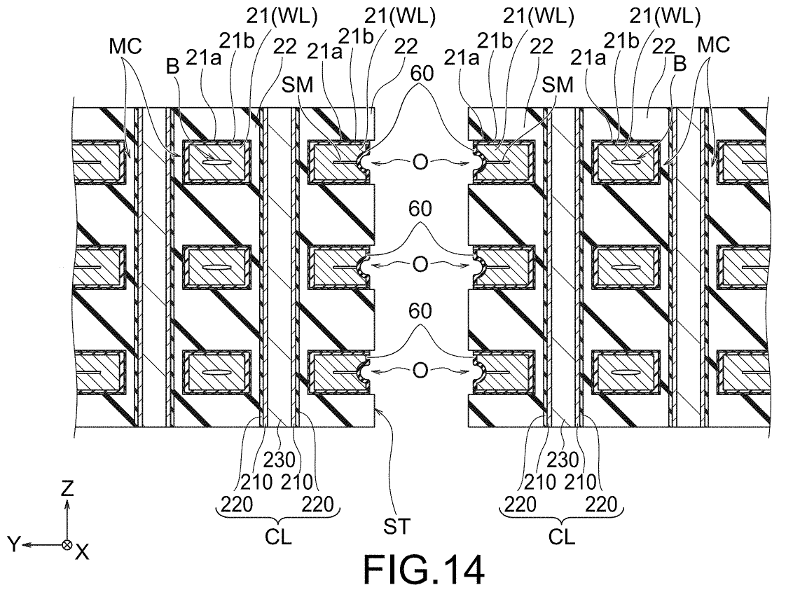

Next, as illustrated in FIG. 14, the metal silicide film 60 is formed on a side surface of each electrode film 21, which faces the slit ST and is exposed. For the metal silicide film 60, molybdenum silicide MoxSiy is used, for example. The thickness of the metal silicide film 60 is about 5 angstroms to 5 nm.

The metal silicide film 60 may be formed by converting the side surface of the electrode film 21 into silicide or by being deposited on the side surface of the electrode film 21 via the slit ST. In a case of converting the side surface of the electrode film 21 into silicide, it suffices that the side surface of the electrode film 21 is selectively converted into silicide via the slit ST. For example, the side surface of the electrode film 21 is recessed in a direction away from the slit ST (±Y-directions), and the side surface of the electrode film 21 is exposed to a silicon-containing gas at a temperature of 200° C. or higher. Consequently, the side surface of the electrode film 21 is selectively turned into silicide, so that the metal silicide film 60 is formed on the side surface of the electrode film 21. In this case, an end of the barrier film 21b exposed to the slit ST is turned into metal silicide or a silicon oxide film. For example, in a case where the barrier film 21b is made of aluminum oxide, the end of the barrier film 21b exposed to the slit ST is turned into a silicon oxide film. In a case where the barrier film 21b is made of titanium nitride, the end of the barrier film 21b exposed to the slit ST is turned into titanium silicide or a silicon oxide film. At this time, the end of the barrier film 21b exposed to the slit ST faces (is in contact with) the insulation film 51, and the metal silicide film 60 is not formed at that end.

In a case of deposition on the side surface of the electrode film 21 via the slit ST, a material for the metal silicide film 60 is deposited on the inner wall of the slit ST by ALD (Atomic Layer Deposition) or CVD (Chemical Vapor Deposition). It suffices that the material for the metal silicide film 60 is then etched back to be left only on the side surface of the electrode film 21. In this case, since the side surface of the electrode film 21 is recessed in the direction away from the slit ST (±Y-directions), the side surface of the electrode film 21 is depressed with respect to a side surface of the insulation film 22 in the direction away from the slit ST. Therefore, the material for the metal silicide film 60 is formed at a position that is depressed with respect to the side surface of the insulation film 22 in the direction away from the slit ST. Accordingly, by anisotropically etching back the material for the metal silicide film 60 by RIE (Reactive Ion Etching) or the like, the material for the metal silicide film 60 on the side surface of the electrode film 21 can be selectively left with that material on the side surface of the insulation film 22 removed. Accordingly, the metal silicide film 60 can be selectively formed only on the side surface of the electrode film 21. In this case, the metal silicide film 60 is formed at the end of the barrier film 21b exposed to the slit ST.

In the present embodiment, no metal silicide film is formed on the inner surface of the void B. For example, as described above, in a case where the void B does not communicate with outside, the metal silicide film 60 is formed on the side surface of the electrode film 21 but is not formed on the inner surface of the void B.

The metal silicide film 60 can prevent oxygen entering via the slit ST from reaching the electrode film 21 and therefore can prevent oxidation of the electrode film 21.

Any of tungsten silicide (WSi), ruthenium silicide (RuSi), cobalt silicide (CoSi), molybdenum silicide (MoSi), nickel silicide (NiSi), and titanium silicide (TiSi) may be used for the metal silicide film 60, for example. In this case, any of tungsten (W), ruthenium (Ru), cobalt (Co), molybdenum (Mo), nickel (Ni), and titanium (Ti) may be used for the electrode films 21, for example.

Next, as illustrated in FIG. 6, the insulation film 51 is formed on the inner wall of the slit ST, and a material for the wire 50 is embedded inside the insulation film 51. At this time, oxygen diffused from the insulation film 51 or the wire 50 is blocked by the metal silicide film 60 and scarcely reaches the electrode film 21. Accordingly, oxidation of the electrode film 21 can be prevented, so that increase of the resistance thereof can be prevented.

Thereafter, a multilayer wiring layer, a bit line, and the like are formed on the stack 2. The semiconductor storage device 100a according to the present embodiment is completed in this manner. The semiconductor storage device 100a may be formed by bonding a CMOS circuit (the base portion 1) and the memory cell array 2m (the stack 2), respectively formed on separate substrates, to each other.

### Second Embodiment

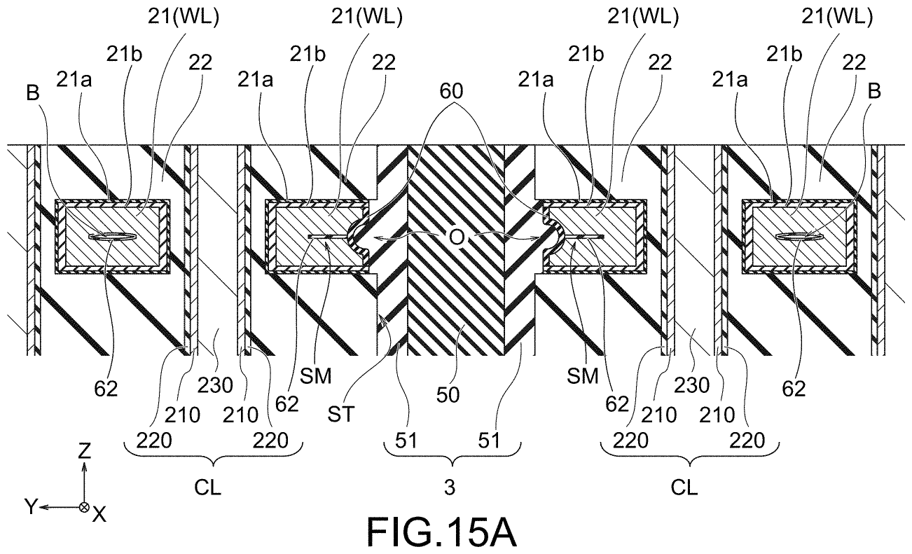

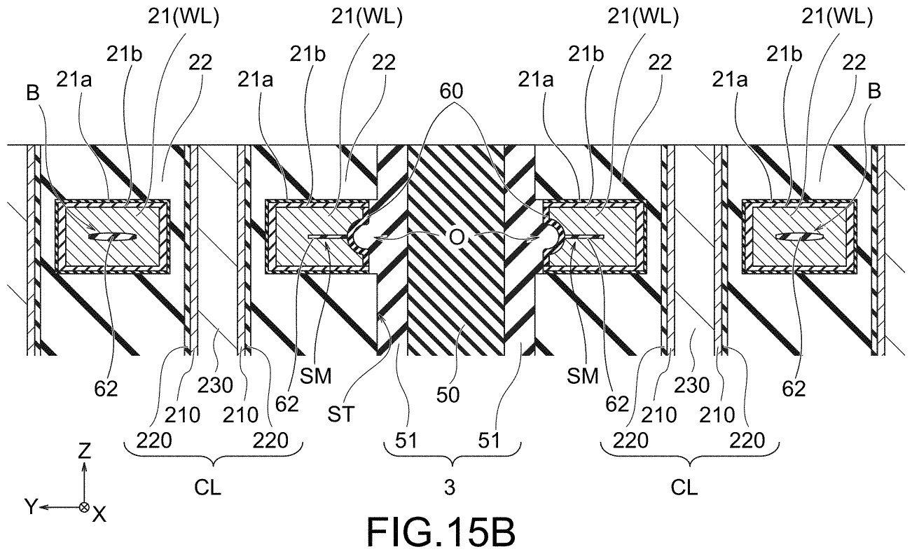

FIG. 15A is a cross-sectional view illustrating a configuration example of the semiconductor storage device 100a according to a second embodiment. In the semiconductor storage device 100a according to the second embodiment, a metal silicide film 62 is provided also on the inner wall of the void B and/or the inner wall of the seam SM within the electrode film 21. For example, in a case where the void B communicates with outside, the metal silicide films 60 and 62 are formed not only on the side surface of the electrode film 21 but also on the inner surface of the void B as descried above. For the metal silicide film 62, any of tungsten silicide (WSi), ruthenium silicide (RuSi), cobalt silicide (CoSi), molybdenum silicide (MoSi), nickel silicide (NiSi), and titanium silicide (TiSi) is used, for example. The metal silicide film 62 may be made of the same material as the metal silicide film 60 or a different material from the metal silicide film 60. For example, the metal silicide film 60 may be made of molybdenum silicide, and the metal silicide film 62 may be made of tungsten silicide, or vice versa. The thickness of the metal silicide film 62 is, for example, about 5 angstroms to 5 nm. The rest of the configurations of the second embodiment may be identical to those of the first embodiment.

According to the second embodiment, the metal silicide film 62 is provided also on the inner wall of the void B and/or the inner wall of the seam SM. Accordingly, even when oxygen is present in the void B or the seam SM, that oxygen can be prevented from entering into the electrode film 21 and being diffused in the electrode film 21. Consequently, the semiconductor storage device 100a according to the second embodiment can maintain the resistance of each electrode film 21 at a lower level more reliably.

A manufacturing method of the semiconductor storage device 100a according to the second embodiment may be identical to the manufacturing method according to the first embodiment. In a case where the void B communicates with outside, the metal silicide films 60 and 62 are formed not only on the side surface of the electrode film 21 but also on the inner surface of the void B by exposing the side surface of the electrode film 21 to a silicon-containing gas at a temperature of 200° C. or higher. Alternatively, the materials for the metal silicide films 60 and 62 may be deposited on the inner wall of the slit ST by ALD or the like and then etched back. Also in this case, the metal silicide films 60 and 62 can be formed not only on the side surface of the electrode film 21 but also on the inner surface of the void B. In this case, the metal silicide films 60 and 62 are made of the same material as each other. A cavity (a void) may be left within the metal silicide film 62 in the void B. Alternatively, the void B and the seam SM may be embedded (filled) with the material for the metal silicide film 62.

However, in a case where the metal silicide films 60 and 62 are made of materials different from each other, the material for the metal silicide film 62 is formed on the side surface of the electrode film 21 and in the void B and the seam SM, and the material for the metal silicide film 62 on the side surface of the electrode film 21 is removed by CDE (Chemical Dry Etching). In this removal, the metal silicide film 62 in the void B and the seam SM is left. Next, the metal silicide film 60 is formed on the side surface of the electrode film 21. At this time, since the metal silicide film 62 is formed in the void B and the seam SM, the material for the metal silicide film 60 is formed on the side surface of the electrode film 21 but does not enter into the void B and the seam SM. Accordingly, the metal silicide films 60 and 62 can be made of different materials from each other.

FIG. 15B is a cross-sectional view illustrating a configuration example of the semiconductor storage device 100a according to a modification of the second embodiment. According to this modification, the metal silicide film 62 is filled in the void B and/or the seam SM within the electrode film 21. Even in this mode, the effects of the second embodiment are not lost.

### Third Embodiment

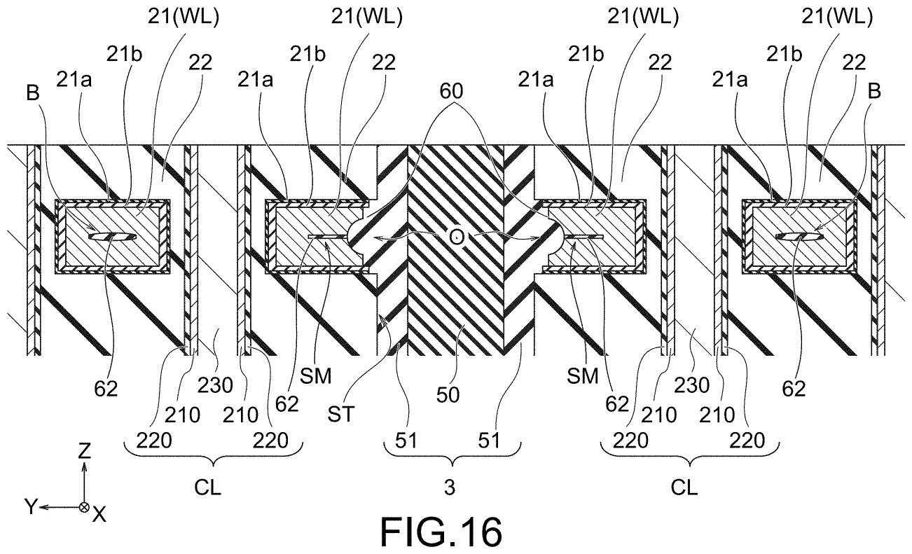

FIG. 16 is a cross-sectional view illustrating a configuration example of the semiconductor storage device 100a according to a third embodiment. In the semiconductor storage device 100a according to the third embodiment, the metal silicide film 62 is provided on the inner wall of the void B and/or the inner wall of the seam SM within the electrode film 21, but the metal silicide film 60 is not provided on the side surface of the electrode film 21 on the slit ST side. The rest of the configurations of the third embodiment may be identical to those of the second embodiment.

Since the metal silicide film 60 is not provided on the side surface of the electrode film 21 on the slit ST side, an effect of preventing entrance of oxygen from the side surface of the electrode film 21 which faces the slit ST is limited. However, entrance of oxygen from the void B and/or the seam SM within the electrode film 21 can be prevented. Therefore, also in the third embodiment, the effect of preventing oxidation of the electrode film 21 can be obtained to some extent.

As in the first or third embodiment, one of the metal silicide films 60 and 62 is not necessarily formed. Therefore, the electrode films 21 in one stack 2 may include the electrode films 21 according to the first to third embodiments in a mixed manner. For example, only the metal silicide film 60 may be formed for a portion of the word lines WL of the stack 2, only the metal silicide film 62 may be formed for another portion of the word lines WL, and both the metal silicide films 60 and 62 may be formed for the remaining word line(s) WL. Even in this configuration, the effects of the present embodiment can be obtained to some extent.

### Fourth Embodiment

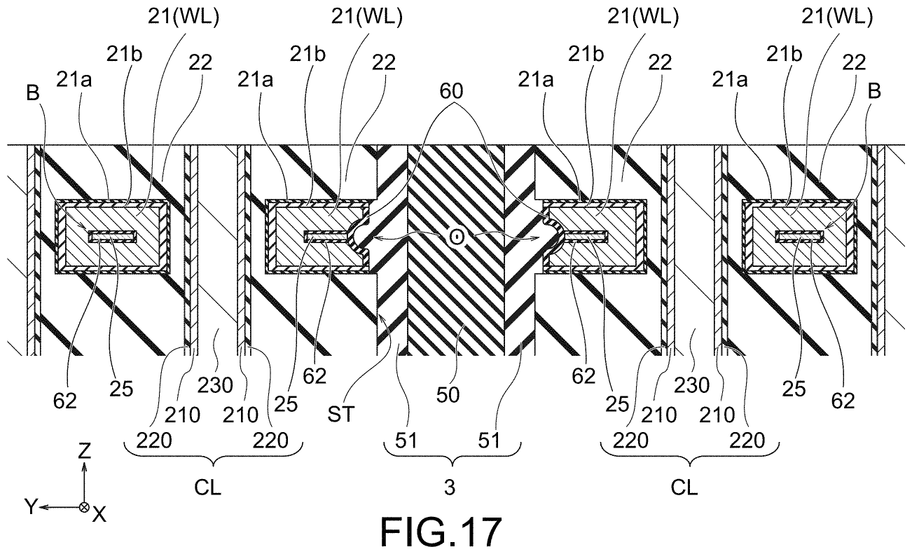

FIG. 17 is a cross-sectional view illustrating a configuration example of the semiconductor storage device 100a according to a fourth embodiment. The semiconductor storage device 100a according to the fourth embodiment is provided with the metal silicide film 62 on the inner wall of the void B within the electrode film 21 and further includes an embedding member 25 made of the same material as the electrode film 21 and embedded in the metal silicide film 62. A material for the embedding member 25 may be different from that for the electrode films 21. The material for the embedding member 25 may be conductive or insulative. The rest of the configurations of the fourth embodiment may be identical to those of the second embodiment.

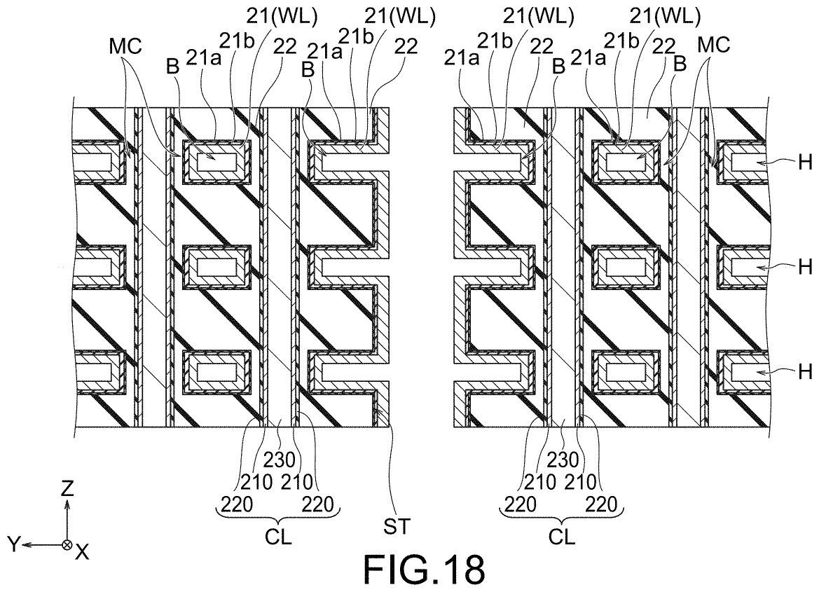

FIGS. 18 to 21 are cross-sectional views illustrating an example of a manufacturing method of the semiconductor storage device 100a according to the fourth embodiment.

After the processes described with reference to FIGS. 9 to 12, the block insulation film 21a and the barrier film 21b are formed on the inner wall of the cavity H via the slit ST. Further, as illustrated in FIG. 18, a material for the electrode films 21 is deposited on the barrier film 21b. The void B is generated within the electrode film 21.

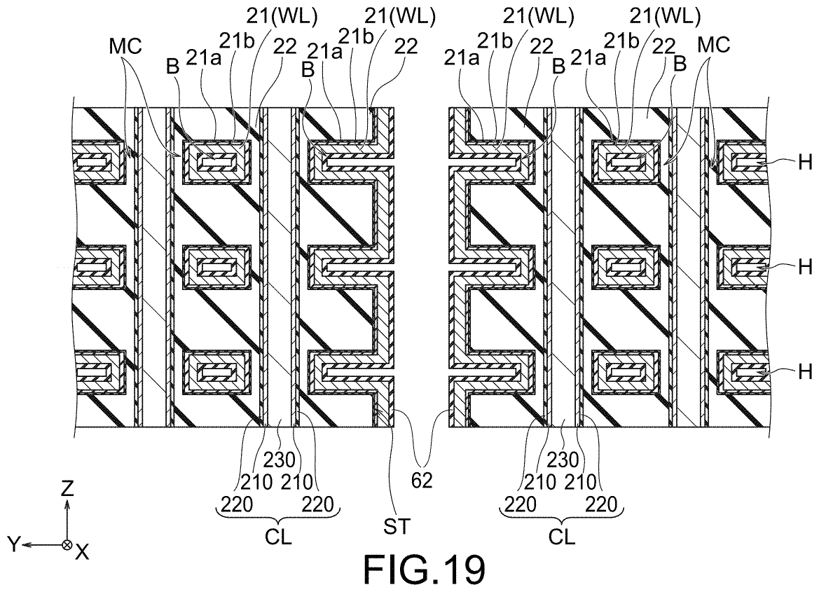

Next, as illustrated in FIG. 19, a material for the metal silicide film 62 is deposited on the inner wall of the void B by ALD or CVD.

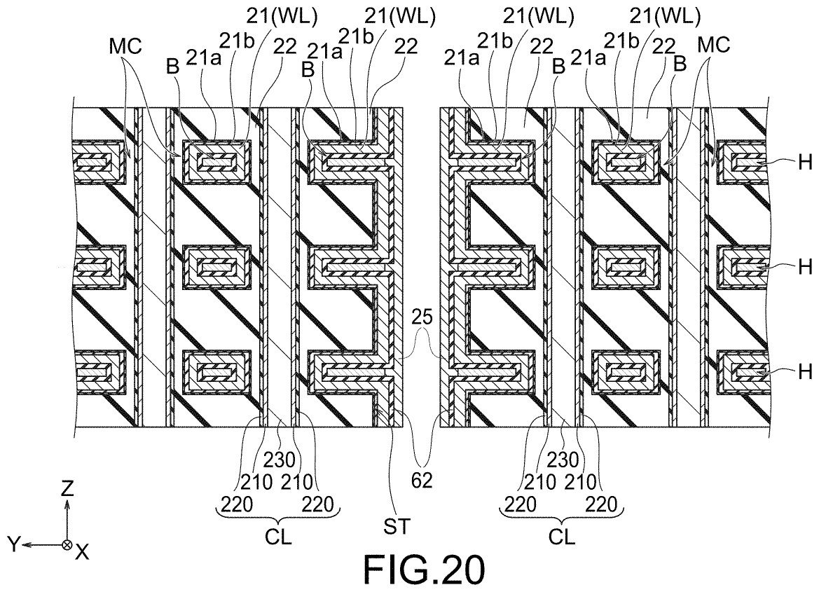

Next, as illustrated in FIG. 20, the embedding member 25 is embedded in the void B within the silicide film 62.

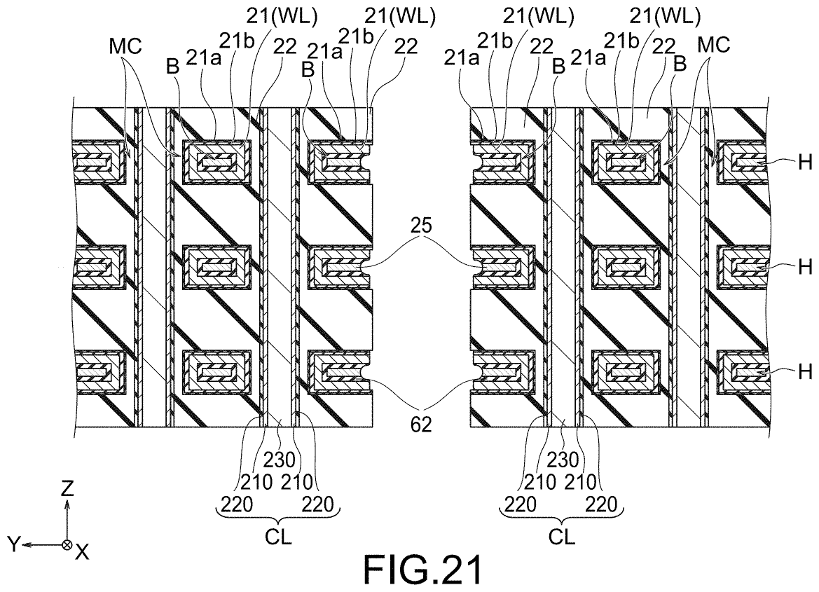

Next, as illustrated in FIG. 21, the embedding member 25, the metal silicide film 62, and the electrode film 21 are etched back to be left in the cavity H in FIG. 12. The block insulation film 21a and the barrier film 21b may be also etched back to be left in the cavity H.

Thereafter, as described with reference to FIG. 14, the metal silicide film 60 is formed on a side surface of the electrode film 21 which faces the slit ST and is exposed.

Next, as illustrated in FIG. 17, the insulation film 51 is formed on the inner wall of the slit ST, and a material for the wire 50 is embedded inside the insulation film 51. At this time, oxygen diffused from the insulation film 51 or the wire 50 is blocked by the metal silicide films 60 and 62 and scarcely reaches the electrode film 21. Accordingly, it is possible to prevent oxidation of the electrode film 21 and increase of the resistance thereof.

Thereafter, a multilayer wiring layer, a bit line, and the like are formed on the stack 2. The semiconductor storage device 100a according to the fourth embodiment is completed in this manner.

### Application Example

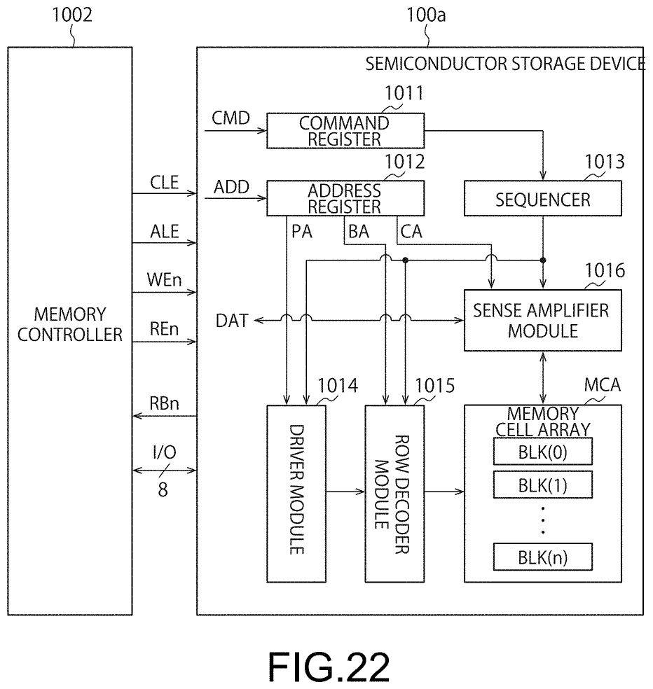

FIG. 22 is a block diagram illustrating a configuration example of a semiconductor storage device to which any of the embodiments described above is applied. The semiconductor storage device 100a is a NAND flash memory that can store therein data in a non-volatile manner, and is controlled by an external memory controller 1002. Communication between the semiconductor storage device 100a and the memory controller 1002 supports, for example, a NAND interface standard.

As illustrated in FIG. 22, the semiconductor storage device 100a includes, for example, a memory cell array MCA, a command resister 1011, an address resister 1012, a sequencer 1013, a driver module 1014, a row decoder module 1015, and a sense amplifier module 1016.

The memory cell array MCA includes a plurality of blocks BLK(0) to BLK(n) (n is an integer of 1 or more). Each block BLK is a set of a plurality of memory cells capable of storing therein data in a non-volatile manner and is used as, for example, the unit of erasing data. The memory cell array MCA is provided with a plurality of bit lines and a plurality of word lines. Each memory cell is associated with one bit line and one word line, for example. A detailed configuration of the memory cell array MCA will be described later.

The command resister 1011 retains a command CMD received by the semiconductor storage device 100a from the memory controller 1002. The command CMD includes, for example, an instruction to cause the sequencer 1013 to perform a read operation, a write operation, an erase operation, or the like.

The address resister 1012 retains address information ADD received by the semiconductor storage device 100a from the memory controller 1002. The address information ADD includes, for example, a block address BA, a page address PA, and a column address CA. For example, the block address BA, the page address PA, and the column address CA are used for selecting the blocks BLK, the word lines, and the bit lines, respectively.

The sequencer 1013 controls the operation of the whole semiconductor storage device 100a. For example, the sequencer 1013 controls the driver module 1014, the row decoder module 1015, the sense amplifier module 1016, and the like based on the command CMD retained in the command resister 1011 to perform a read operation, a write operation, an erase operation, or the like.

The driver module 1014 generates a voltage used in a read operation, a write operation, an erase operation, or the like. The driver module 1014 then applies the generated voltage to a signal line corresponding to a selected word line, for example, based on the page address PA retained in the address register 1012.

The row decoder module 1015 includes a plurality of row decoders. The row decoder selects, based on the block address BA retained in the address resister 1012, one block BLK in the corresponding memory cell array MCA. The row decoder then transfers, for example, the voltage applied to the signal line corresponding to the selected word line to the selected word line in the selected block BLK.

The sense amplifier module 1016 applies a desired voltage to each bit line in accordance with write data DAT received from the memory controller 1002 in a write operation. Further, in a read operation, the sense amplifier module 1016 determines data stored in a memory cell based on a voltage of a bit line, reads out the determination result, and transfers the determination result as data DAT to the memory controller 1002.

The semiconductor storage device 100a and the memory controller 102 explained above may be combined to constitute a single semiconductor device. Examples of such a semiconductor device are memory cards such as an SD™ card, SSDs (solid state drive), and the like.

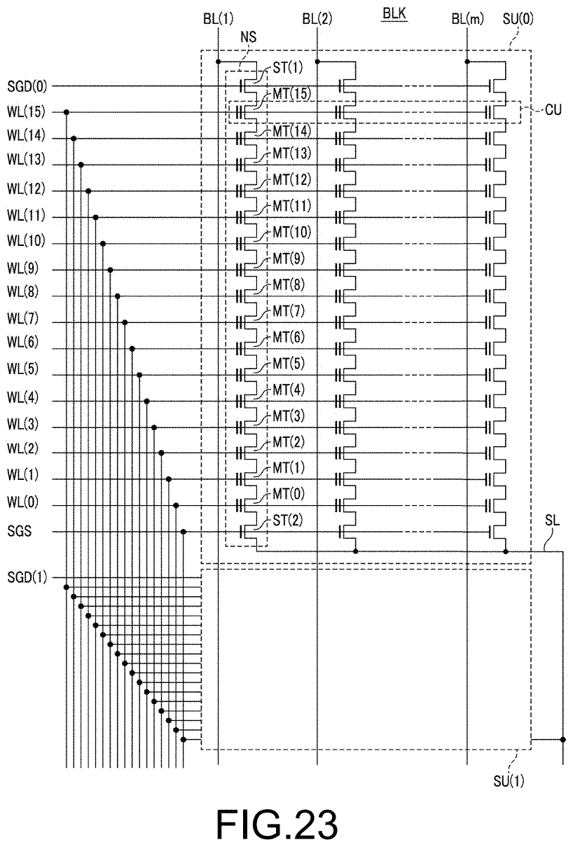

FIG. 23 is a circuit diagram illustrating an example of a circuit configuration of the memory cell array MCA. One block BLK is extracted from the blocks BLK included in the memory cell array MCA. As illustrated in FIG. 23, the block BLK includes a plurality of string units SU(0) to SU(k) (k is an integer of 1 or more).

Each string unit SU includes a plurality of NAND strings NS respectively associated with bit lines BL(0) to BL(m) (m is an integer of 1 or more). Each NAND string NS includes, for example, memory cell transistors MT(0) to MT(15) and selection transistors ST(1) and ST(2). The memory cell transistor MT includes a control gate and a charge storage layer and retains data in a non-volatile manner. Each of the selection transistors ST(1) and ST(2) is used for selecting the string unit SU in various operations.

In each NAND string NS, the memory cell transistors MT(0) to MT(15) are connected in series. A drain of the selection transistor ST(1) is connected to an associated bit line BL, and a source of the selection transistor ST(1) is connected to one end of a series of the memory cell transistors MT(0) to MT(15) connected in series. A drain of the selection transistor ST(2) is connected to the other end of the series of the memory cell transistors MT(0) to MT(15) connected in series. A source of the selection transistor ST(2) is connected to a source line SL.

In the same block BLK, the control gates of the memory cell transistors MT(0) to MT(15) are connected in common to word lines WL(0) to WL(15), respectively. Gates of the selection transistors ST(1) in the string units SU(0) to SU(k) are connected in common to selection gate lines SGD(0) to SGD(k), respectively. Gates of the selection transistors ST(2) are connected in common to a selection gate line SGS.

In the circuit configuration of the memory cell array MCA described above, each bit line BL is shared by the NAND strings NS in the respective string units SU, to which the same column address is assigned. The source line SL is shared by, for example, the blocks BLK.

A set of the memory cell transistors MT connected to the common word line WL in one string unit SU is referred to as “cell unit CU”, for example. For example, the storage capacity of the cell unit CU including the memory cell transistors MT each storing therein 1-bit data is defined as “1-page data”. The cell unit CU can have a storage capacity of 2-page data or more in accordance with the number of bits of data stored in the memory cell transistors MT.

The memory cell array MCA included in the semiconductor storage device 100a according to the present embodiment is not limited to the circuit configuration described above. For example, each of the numbers of the memory cell transistors MT and the selection transistors ST(1) and ST(2) included in each NAND string NS can be designed to be any number. The number of the string units SU included in each block BLK can be designed to be any number.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a stack including a plurality of electrode films stacked in a first direction to be separated from each other;
a column portion extending in the stack in the first direction, including a semiconductor layer, and having memory cells at respective intersections of the semiconductor layer and the electrode films;
a dividing portion extending in the stack in the first direction and a second direction crossing the first direction, dividing the electrode films in a third direction crossing the first direction and the second direction, and including an insulator; and
a first film provided between the insulator and an end surface in the third direction of each of the electrode films and containing a first metal and silicon.

2. The device of claim 1, wherein the first film is provided on an opposed surface of the electrode film which is opposed to the dividing portion.

3. The device of claim 1, wherein the first film covers a side surface of the electrode film on a side of the dividing portion.

4. The device of claim 1, wherein any of molybdenum silicide, tungsten silicide, titanium silicide, ruthenium silicide, cobalt silicide, and nickel silicide is used for the first film.

5. The device of claim 1, further comprising a second film provided on an inner wall of a cavity portion within the electrode film and containing a second metal and silicon.

6. The device of claim 5, wherein the second film is provided on an inner wall of a void or a seam within the electrode film.

7. The device of claim 5, wherein the second film is filled in a void or a seam within the electrode film.

8. The device of claim 5, wherein any of molybdenum silicide, tungsten silicide, titanium silicide, ruthenium silicide, cobalt silicide, and nickel silicide is used for the second film.

9. The device of claim 5, wherein materials different from each other are used for the first and second films.

10. The device of claim 5, further comprising a material film provided within the second film in the cavity portion.

11. A manufacturing method of a semiconductor device, comprising:
forming a stack by alternately stacking a plurality of first insulation films and a plurality of first sacrifice films in a first direction;
forming a plurality of column portions extending in the stack in the first direction, each containing a semiconductor layer, and each having memory cells at respective intersections of the semiconductor layer and a plurality of electrode films;
forming a slit penetrating through the stack in the first direction;
replacing the first sacrifice films with the electrode films via the slit;
forming a first film containing a first metal and silicon on a side surface of each of the electrode films, the side surface being exposed to the slit; and
forming a second insulation film on an inner wall of the slit.

12. The method of claim 11, wherein any of molybdenum silicide, tungsten silicide, titanium silicide, ruthenium silicide, cobalt silicide, and nickel silicide is used for the first film.

13. The method of claim 11, further comprising forming a second film containing a second metal and silicon on an inner wall of a cavity portion within the electrode film.

14. The method of claim 13, wherein the second film is formed on an inner wall of a void or a seam within the electrode film.

15. The method of claim 13, wherein the second film is filled in a void or a seam within the electrode film.

16. The method of claim 13, wherein any of molybdenum silicide, tungsten silicide, titanium silicide, ruthenium silicide, cobalt silicide, and nickel silicide is used for the second film.

17. The method of claim 13, wherein materials different from each other are used for the first and second films.

18. The method of claim 13, further including forming a material film within the second film in the cavity portion.
